(19) United States
(12) Patent Application Publication
(10) Pub. No.: US 2026/0223513 A1
(43) Pub. Date: Jul. 30, 2026

(54) MATRIX DISPLAY AND ITS PREPARATION METHOD

(71) Applicant: GUANGDONG OPSCO TECHNOLOGY CO., LTD, Dongguan (CN)

(72) Inventors: MINGJIAN LIU, Dongguan (CN); GENGSHENG ZHU, Dongguan (CN); ZHENLEI WU, Dongguan (CN)

(21) Appl. No.: 19/572,908

(22) Filed: Mar. 20, 2026

Related U.S. Application Data
(63) Continuation of application No. PCT/CN2024/134994, filed on Nov. 27, 2024.

(30) Foreign Application Priority Data
Sep. 26, 2024 (CN) 2024113499632

(51) Int. Cl. H10H 29/852; H10H 29/01; H10H 29/855

(52) U.S. Cl. CPC H10H 29/852; H10H 29/0362; H10H 29/0363; H10H 29/8552

(57) ABSTRACT

The present disclosure provides a matrix display and its preparation method. The matrix display includes an insulating substrate, light-emitting units, first encapsulants, a first light-shielding layer, second encapsulants and a second light-shielding layer; light-emitting units are disposed on the insulating substrate and arranged in a matrix; the first encapsulant is encapsulated on the exterior of the light-emitting unit; the first light-shielding layer is disposed on the insulating substrate; the first encapsulant is located in the first light-shielding layer; the second encapsulant is encapsulated on the first encapsulant and located in the second light-shielding layer.

### CROSS-REFERENCE TO RELATED APPLICATIONS

The present disclosure claims priority of the Chinese Patent application No. 2024113499632 entitled “MATRIX DISPLAY AND ITS PREPARATION METHOD” filed on Sep. 26, 2024, to the China National Intellectual Property Administration, the entire contents of which are incorporated herein by reference.

### FIELD

The present disclosure relates to the technical field of LED, and in particularly to a matrix display and its preparation method.

### BACKGROUND

A matrix display is composed of a plurality of independent small LED display modules, each of which is an independent unit that can be controlled individually. By controlling the brightness or color of each unit, images or texts can be formed. The matrix display can be monochrome or full-color, and it can be either static or dynamic.

However, with the increasing resolution of current images and videos, the requirement for the display precision of the matrix display is also rising steadily, and a matrix display with high display precision is urgently needed.

### SUMMARY

The present disclosure provides a matrix display and its preparation method, aiming to solve the problem that the display precision of current matrix displays cannot meet the current resolution requirements for images and videos.

In the first aspect, an embodiment of the present disclosure provides a matrix display, including:
an insulating substrate;
a plurality of light-emitting units, disposed on the insulating substrate and arranged in a matrix to form an LED array, wherein the light-emitting unit includes a pin, a light-emitting die disposed on the pin, and a driving chip for driving the light-emitting die to emit light;
a plurality of first encapsulants, each first encapsulant is encapsulated on an exterior of each light-emitting unit;
a first light-shielding layer, disposed on the insulating substrate, including a plurality of first through-holes, and the first encapsulant is located in the first through-hole;
a plurality of second encapsulants, each second encapsulant is encapsulated on each first encapsulant, wherein a projected area of the second encapsulant on the insulating substrate is larger than a projected area of the first encapsulant on the insulating substrate;
a second light-shielding layer, disposed on the first light-shielding layer, including a plurality of second through-holes, wherein the second encapsulant is located in the second through-hole;
wherein, when the plurality of light-emitting units emit light, the first light-shielding layer and the second light-shielding layer can block light emitted by the light-emitting unit from exiting sideways, thereby making the light exit from the second through-hole.

In the matrix display, a plurality of light-emitting units are first arranged in a matrix to form an LED array, with each light-emitting unit including a light-emitting die and a driving chip; then, the light-emitting units are wrapped by the first and second layers of encapsulants for protection, and at the same time, the through-hole design of the first and second light-shielding layers realizes front light projection; finally, the two layers of light-shielding layers ensure that light exits the through-holes, reducing the scattering of side light.

Furthermore, the provided matrix display ensures that light is only emitted from the front through the designs of multiple light-shielding layers and encapsulants, avoiding the light from exiting sideways and improving the light-emitting effect. At the same time, the two layers of light-shielding layers block unnecessary side light leakage, reducing optical interference between different light-emitting units and optimizing the display effect. Through the design of the light-shielding layers, optical crosstalk interference between light-emitting units is prevented, and the design of multiple layers of encapsulants protects the light-emitting units, improving the stability and durability of the matrix display.

In the second aspect, an embodiment of the present disclosure provides a preparation method for a matrix display, including:
providing an insulating substrate, wherein the insulating substrate includes a plurality of light-emitting units, the plurality of light-emitting units are arranged in a matrix to form an LED array, and the light-emitting unit includes a pin, a light-emitting die disposed on the pin, and a driving chip for driving the light-emitting die to emit light;
performing a first molding on the insulating substrate to form a plurality of first encapsulants on exteriors of the plurality of light-emitting units disposed on the insulating substrate;
performing a second molding according to a shape and position of the first encapsulant to obtain a first light-shielding layer, wherein the first light-shielding layer includes a plurality of first through-holes;
disposing the first light-shielding layer on the insulating substrate, with the first encapsulant located in the first through-hole;
performing a third molding on the first light-shielding layer to form a target adhesive layer on the first light-shielding layer;
dicing the target adhesive layer to obtain a plurality of second encapsulants and a flow channel; wherein the plurality of second encapsulants are respectively disposed on the plurality of first encapsulants, and a projected area of the second encapsulant on the insulating substrate is larger than a projected area of the first encapsulant on the insulating substrate; and
disposing a second light-shielding layer on an exterior of the second encapsulant through the flow channel, wherein the second light-shielding layer includes a plurality of second through-holes, and the second encapsulant is located in the second through-hole.

The provided method first forms the first encapsulants, the first light-shielding layer, and the second encapsulants through three molding processes respectively to ensure precise matching of the encapsulants and the light-shielding layer; then, the flow channel is used to precisely control the position of the second light-shielding layer to ensure that light exits the through-holes forward; and then, the target adhesive layer is diced to form the second encapsulants, whose area is ensured to be larger than that of the first encapsulants, further optimizing light control and protection of the light-emitting unit; finally, through the design of two layers of light-shielding layers and two layers of encapsulants, light exits the front through the through-hole structure, and side light leakage is avoided.

In summary, the provided method precisely controls the encapsulation of the light-emitting units and the light emission direction through multiple moldings and the design of the flow channel, ensuring that light emits from the front. At the same time, the molding process ensures the precise positioning of the encapsulation and the light-shielding layer, reducing light interference and improving light-emitting efficiency. It solves the problem of precise matching between the encapsulants and the light-shielding layers, avoids light leakage from sideways, and reduces interference between light-emitting units.

It should be understood that the above general description and the following detailed description are only exemplary and explanatory, and cannot limit the present disclosure.

### BRIEF DESCRIPTION OF THE DRAWINGS

In order to more clearly illustrate the technical solutions of the embodiments of the present disclosure, the following will briefly introduce the drawings used in the description of the embodiments. Apparently, the drawings in the following description are some embodiments of the present disclosure. For those of ordinary skill in the art, without making any creative efforts, other drawings can be obtained based on these drawings.

FIG. 1 is a structural schematic diagram of a matrix display provided in an embodiment of the present disclosure.

FIG. 2 is a front view of the matrix display provided in FIG. 1.

FIG. 3 is an exploded schematic diagram of the matrix display provided FIG. 1.

FIG. 4 is a structural schematic block diagram of a single light-emitting unit of the matrix display provided in FIG. 1.

FIG. 5 is a structural schematic block diagram of the first conductive sheet, the second conductive sheet and the signal input unit of the matrix display provided in FIG. 1.

FIG. 6 is a structural schematic block diagram of the protection board of the matrix display provided in FIG. 1.

FIG. 7 is a structural schematic block diagram of the first light-shielding layer and the first encapsulant of the matrix display provided in FIG. 1.

FIG. 8 is a schematic flow chart of the steps of the preparation method provided in an embodiment of the present disclosure.

### MAIN COMPONENTS AND SYMBOLS DESCRIPTION

10, matrix display; 11, insulating substrate; 111, conductive through-hole; 12, light-emitting unit; 121, driving chip; 122, light-emitting die; 123, pin; 1231, ground pin; 1232, power pin;1233, signal input pin;123l , signal output pin;13, first encapsulant; 14, first light-shielding layer; 141, first through-hole; 15, second encapsulant; 16, second light-shielding layer; 161, second through-hole; 17, first conductive sheet; 18, second conductive sheet; 19, surface mount board; 10a, conductive post; 10b, signal input unit;10b1, signal input terminal;10b2, signal input interface.

It should be understood that the above general description and the following detailed description are only exemplary and explanatory, and cannot limit the present disclosure.

### Detailed Description

The technical solution of embodiments of the present disclosure is clearly and completely described in detail in connection with the accompanying drawings. Apparently, described embodiments are some embodiments of the present disclosure, not all embodiments. Based on embodiments of the present disclosure, all other embodiments obtained by those of ordinary skill in the art without creative efforts are within the scope of the present disclosure.

The flowcharts shown in the drawings are merely for illustrative purposes. They do not necessarily include all the content and operations/steps, nor do they have to be executed in the described order. For example, some operations/steps can be further split, combined, or partially merged, so the actual execution order may change according to the actual situation.

It should be understood that the terms used in the specification of the present disclosure are merely for the purpose of describing specific embodiments and are not intended to limit the present disclosure. As used in the specification of the present disclosure and the appended claims, unless the context clearly dictates, otherwise, the singular forms “a”, “an”, and “the” are intended to include the plural forms.

It should be understood that, in order to clearly describe the technical solutions of the embodiments of the present disclosure, in the embodiments of the present disclosure, terms such as “first” and “second” are used to distinguish identical or similar items with basically the same functions and effects. For example, the first encapsulant and the second encapsulant are merely used to distinguish different supporting members, and there is no limitation on their sequence. Those skilled in the art can understand that terms such as “first” and “second” do not limit the quantity or the execution order, and terms such as “first” and “second” do not necessarily mean that they are different.

It should be further understood that the term “and/or” used in the specification and the appended claims of the present disclosure refers to any combination and all possible combinations of one or more of the items listed in association, and includes these combinations.

A matrix display is composed of a plurality of independent small LED display modules, each of which is an independent unit that can be controlled individually. By controlling the brightness or color of each unit, images or texts can be formed. The matrix display can be monochrome or full-color, and it can be either static or dynamic.

However, with the increasing resolution of current images and videos, the requirement for the display precision of the matrix display is also rising steadily, and a matrix display with high display precision is urgently needed.

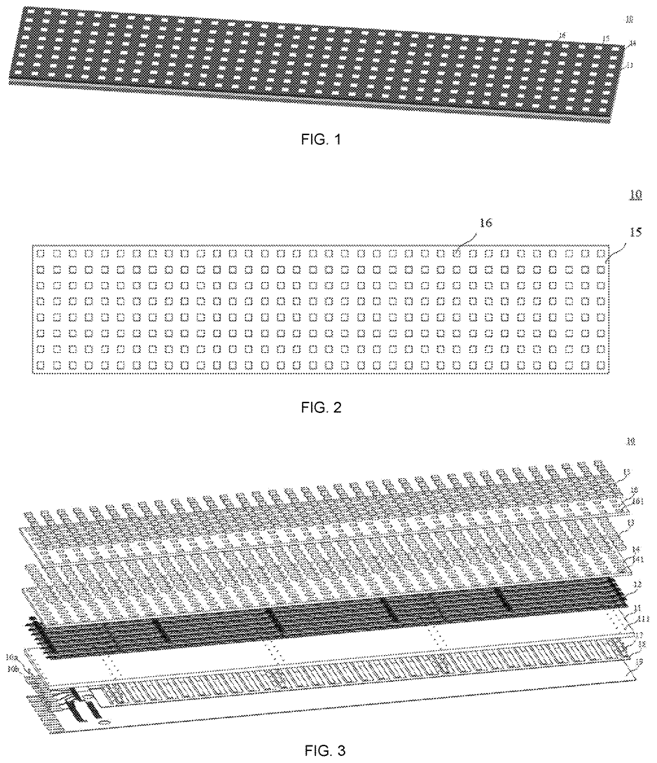

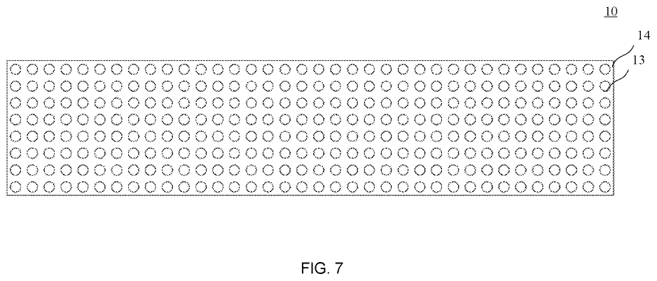

Please refer to FIGS. 1 to 7. An embodiment of the present disclosure provides a matrix display 10, which includes an insulating substrate 11, a plurality of light-emitting units 12, a plurality of first encapsulants 13, a first light-shielding layer 14, a plurality of second encapsulants 15, and a second light-shielding layer 16. Light-emitting units 12 are disposed on the insulating substrate 11, the plurality of light-emitting units 12 are arranged in a matrix to form an LED array, and the light-emitting unit 12 includes a pin 123, a light-emitting die 122 disposed on the pin 123, and a driving chip 121 for driving the light-emitting die 122 to emit light. Each first encapsulant 13 is encapsulated on an exterior of each light-emitting unit 12. The first light-shielding layer 14 is disposed on the insulating substrate 11, the first light-shielding layer 14 includes a plurality of first through-holes 141, and the first encapsulants 13 are located in the first through-holes 141. Each second encapsulant 15 is encapsulated on each first encapsulant 13, wherein a projected area of the second encapsulant 15 on the insulating substrate 11 is larger than a projected area of the first encapsulant 13 on the insulating substrate 11. The second light-shielding layer 16 is disposed on the first light-shielding layer 14, the second light-shielding layer 16 includes a plurality of second through-holes 161, and the second encapsulants 15 are located in the second through-holes 161. Wherein, when the plurality of light-emitting units 12 emit light, the first light-shielding layer 14 and the second light-shielding layer 16 can block the light emitted by the light-emitting units 12 from exiting sideways, thereby making the light exit from the second through-holes 161.

Specifically, the provided matrix display 10 includes an insulating substrate 11, a plurality of light-emitting units 12 (forming an LED array), a plurality of first encapsulants 13, a first light-shielding layer 14, a plurality of second encapsulants 15, and a second light-shielding layer 16. By arranging the light-emitting units 12 including a pin 123, a light-emitting die 122 and a driving chip 121 in a matrix, using the first encapsulant 13 to encapsulate each light-emitting unit 12, making the second encapsulant 15 encapsulated on the first encapsulant 13 and the projected area of the second encapsulant 15 on the insulating substrate 11 larger, and locating the first encapsulant 13 in the first through-hole 141 of the first light-shielding layer 14 and the second encapsulant 15 in the second through-hole 161 of the second light-shielding layer 16, the first light-shielding layer 14 and the second light-shielding layer 16 can block the side light from the light-emitting units 12, thereby making the light mainly exit f rom the second through-holes 161. By controlling the light emission direction, the clarity and contrast of the matrix display 10 are improved. It reduces light scattering and light interference between displays. At the same time, the design of the double layers of encapsulants and light-shielding layers improves the protection effect and service life of the LED. By controlling the light direction, the loss of invalid light is reduced, and the energy utilization efficiency is correspondingly improved.

In summary, the design of the matrix display 10 provided by the embodiment of the present disclosure realizes precise control of LED light emission through the structure of the multiple layers of encapsulants and light-shielding layers, which is expected to improve display quality, reduce light pollution, and bring improvements in energy efficiency and service life.

In some embodiments, as shown in FIGS. 2, 3, and 7, the shape of the first encapsulant 13 corresponds to the shape of the first through-hole 141, and the shape of the second encapsulant 15 corresponds to the shape of the second through-hole 161; wherein the projected shape of the first encapsulant 13 on the insulating substrate 11 is different from the projected shape of the second encapsulant 15 on the insulating substrate 11.

In the above embodiment, the shape of the first encapsulant 13 corresponds to the shape of the first through-hole 141 and the shape of the second encapsulant 15 corresponds to the shape of the second through-hole 161 in the provided matrix display 10. The projected shapes of the first encapsulant 13 and the second encapsulant 15 on the substrate are different. The design of the light-shielding layers and the through-holes effectively blocks the light from exiting sideways, making the light mainly exit from the second through-holes 161, reducing light scattering, improving the directionality and uniformity of light emission, and enhancing the display effect. And through the design of double layers of encapsulants and different projected shapes, the light emission path is controlled, the display brightness and contrast are improved, and the interference or light pollution caused by light spill is reduced. At the same time, the structure of multiple layers of the first encapsulant 13 and the second encapsulant 15 provides better physical protection for the light-emitting unit 12, which helps to extend the service life of the LED and enhance the ability to resist environmental influences. Through the innovative encapsulation and light-shielding design, this embodiment optimizes the light-emitting effect and service life of the LED matrix display 10 and effectively improves the display quality.

In one embodiment, as shown in FIGS. 2, 3, and 7, the projected shape of the first encapsulant 13 on the insulating substrate 11 is a circle, and the projected shape of the second encapsulant 15 on the insulating substrate 11 is a rectangle. Furthermore, the provided matrix display 10 optimizes the light diffusion and focusing effect through the combined design of circular and rectangular shapes for the first encapsulant 13 and the second encapsulant 15 respectively, and improves the uniformity and clarity of display. The design of the rectangle located within the circle provides better light guidance and protection effects.

It should be noted that, in some embodiments, the rectangle is located within the circle. The center of the rectangle coincides with the center of the circle. Furthermore, the symmetrical light output of the matrix display 10 is ensured through the center coincidence design.

In some embodiments, the type of the first encapsulant 13 is different from the type of the second encapsulant 15; the first encapsulant 13 is either a transparent encapsulant or a diffusion encapsulant, and the second encapsulant 15 is another one among a transparent encapsulant and a diffusion encapsulant which is different from the first encapsulant 13.

The transparent encapsulant has a high transmittance, which can effectively transmit the light emitted by the light-emitting unit 12, and improve the brightness and color purity of the emergent light. The diffusion encapsulant can effectively scatter light, making the light more uniform, reducing bright spots or dark spots, and improving the uniformity of the display effect. Through the combined use of different encapsulants, the high transmittance of the transparent encapsulant and the uniform light distribution effect of the diffusion encapsulant can be combined, so that the light-emitting unit 12 can perform its best under the encapsulation of different layers, and the overall display effect can be optimized. The different type choices of the first encapsulant 13 and the second encapsulant 15 can more accurately control the light emission paths and scattering paths in the design, increase the design flexibility, and help achieve the best display effect. The use of different types of encapsulants also helps to improve the heat dissipation performance of the light-emitting unit 12. Certain encapsulants have higher thermal conductivity, which can effectively dissipate heat, thereby extending the life of the light-emitting unit 12. At the same time, the combined use of different types of encapsulants provides more design options, allowing engineers to have greater flexibility in designing and adjusting optical performance. By reasonably selecting the types of transparent encapsulant and diffusion encapsulant, the light efficiency can be improved while reducing the light interference on surrounding components, and the overall performance of the optical system can be further optimized. The provided matrix display 10 can adapt to different usage scenarios and customer needs. In some cases, higher brightness light output is required, while in other cases, more uniform light distribution is required. Through this measure, the product characteristics can be flexibly adjusted according to the needs.

In summary, by adopting different types of encapsulants (the transparent encapsulant and the diffusion encapsulant) in the design of the matrix display 10 to optimize the optical performance of different layers, not only the display effect and optical performance of the LED matrix display 10 are enhanced, but also greater design flexibility and adaptability are provided. At the same time, it can effectively improve the reliability and service life of the product and meet the needs of different application scenarios.

In some embodiments, the thickness of the first through-hole 141 is greater than or equal to the thickness of the first encapsulant 13. Furthermore, it is ensured that the first encapsulant 13 is completely surrounded by the first through-hole 141, which helps to better control the initial diffusion and direction of light. And it provides sufficient space for the first encapsulant 13 to prevent the encapsulant from overflowing or being squeezed, and protects the integrity of the light-emitting unit 12. By providing additional space for heat dissipation, it helps to improve the heat dissipation performance of the LED. It provides a certain tolerance space in the production process to facilitate the injection and molding of the encapsulant.

In some embodiments, the thickness of the second through-hole 161 is greater than or equal to the thickness of the second encapsulant 15. Furthermore, it is ensured that the second encapsulant 15 is completely located in the second through-hole 161, and the light emission path and angle are further precisely controlled. And it prevents the second encapsulant 15 from protruding from the surface of the second light-shielding layer 16, maintains the flatness of the display surface, and improves the display quality. At the same time, the second through-hole 161 completely surrounds the second encapsulant 15, maximizing the effect of the light-shielding layer and reducing light leakage. It provides sufficient space for the second encapsulant 15 and enhances the stability and durability of the overall structure.

In some embodiments, the thickness of the first encapsulant 13 is greater than or equal to the thickness of the second encapsulant 15. Furthermore, the thicker first encapsulant 13 helps to initially diffuse and homogenize the light, while the thinner second encapsulant 15 can further finely control the light emergence. The thicker first encapsulant 13 provides better physical protection and insulation effect for the light-emitting unit 12. The thicker first encapsulant 13 helps to better disperse and manage heat and to improve the life and performance of the LED. The thickness configuration provides more possibilities for optical design, and the light output characteristics can be optimized by adjusting the thickness ratio of the two layers of encapsulants. The thicker first encapsulant 13 is easier to manufacture and mold, while the thinner second encapsulant 15 is conducive to fine adjustment and surface treatment.

In summary, any combination of the above three embodiments according to requirements not only optimizes the optical performance and structural stability of the matrix display 10, but also improves the manufacturing feasibility and product durability. Through the elaborately designed thickness configuration, the present disclosure realizes precise control of light output, and at the same time provides sufficient protection and heat dissipation conditions for the matrix display 10.

In some embodiments, the insulating substrate 11 and the first light-shielding layer 14 are BT resin substrates. BT (Bismaleimide Triazine) resin is used as the material of the insulating substrate 11 and the first light-shielding layer 14. BT resin has excellent heat resistance and can maintain stable performance in high-temperature environments. At the same time, due to its low dielectric constant, it helps to reduce signal interference and improve circuit performance. And it also has low moisture absorption, which can reduce the impact of moisture on the circuit and improve the reliability of the product. It can also enhance the stability and durability of the overall structure and ensure effective isolation between circuit components.

In some embodiments, the second light-shielding layer 16 is a light-shielding adhesive layer. It provides better adaptability and processing convenience through the form of adhesive layers. It effectively controls the unintended light scattering and reduces the light interference between devices.

Exemplarily, the color of the light-shielding adhesive layer is black. As shown in FIG. 1, the black material can effectively absorb light of various wavelengths and greatly reduce light leakage. The black background enhances the visual effect of LED light emission and improves the display contrast.

It should be noted that in some embodiments, the color of the insulating substrate 11 and the first light-shielding layer 14 is white. The white surface can reflect the light emitted by the LED and improve the light utilization rate. At the same time, the reflection increases the overall brightness output of the matrix display 10 and improves the display effect. The white surface helps to reflect heat, improve heat distribution, and facilitate the uniform diffusion of light, improving display uniformity. It can also increase light output through reflection and improve overall energy efficiency.

The above embodiments create an efficient, high-contrast display system through combination according to requirements. The BT resin substrate provides good electrical and mechanical properties. The black light-shielding adhesive layer ensures precise light control and high contrast, while the white insulating substrate 11 and the first light-shielding layer 14 optimize light utilization and thermal management. This design not only improves display quality and energy efficiency, but also enhances the overall performance and reliability of the device.

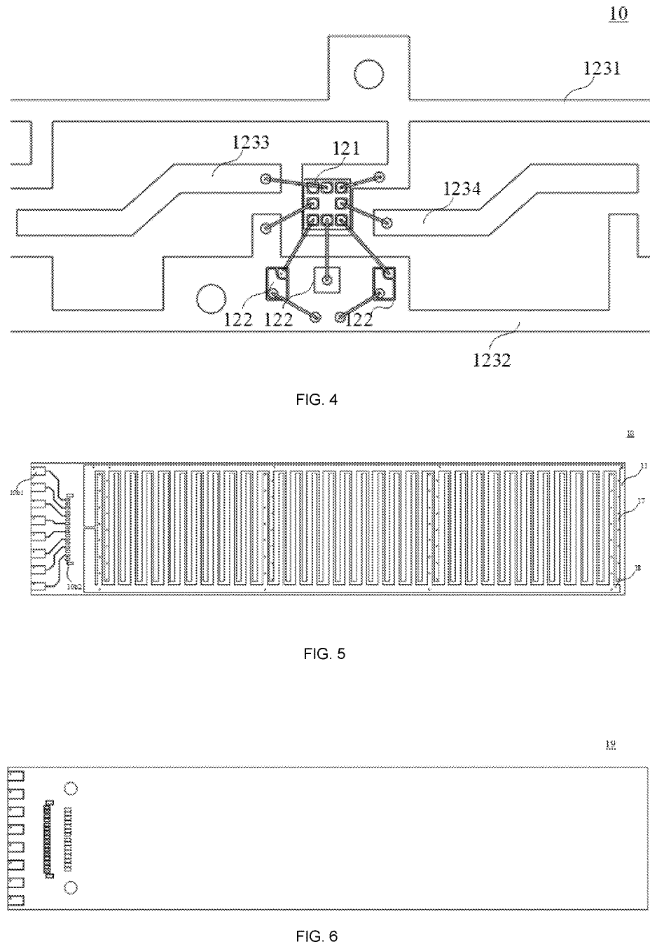

In some embodiments, as shown in FIGS. 3 and 4, the insulating substrate 11 i ncludes a first surface and a second surface opposite to each other; a plurality of rows of pin 123 groups are arranged at intervals on the first surface of the insulating substrate 11, and each row of pin 123 groups includes a plurality of pin 123 pairs; each pin 123 pair includes a power pin 1232, a ground pin 1231, a signal input pin 1233, and a signal output pin 1234; the light-emitting die 122 and the driving chip 121 are electrically connected to the power pin 1232; the driving chip 121 is electrically connected to the ground pin 1231, the signal input pin 1233, and the signal output pin 1234 respectively; wherein the power pins 1232 of the plurality of pin 123 pairs are integrally formed, and the ground pins 1231 of the plurality of pin 123 pairs are integrally formed.

As shown in FIGS. 3 and 4, the design of the provided pin 123 groups optimizes space utilization and improves integration. The integrally formed power pins and ground pins 1231 simplify the circuit layout, reduce resistance, improve power supply efficiency, improve power distribution, and help maintain stable voltage supply. At the same time, the integrally formed pins 123 increase the heat conduction area, which helps to dissipate heat. The adoption of independent signal input and output pins 123 reduces signal interference and enhances signal integrity. Integral formation of the pins 123 simplifies the manufacturing and assembly processes and improves production efficiency. And it reduces the number of independent pins 123, and reduces the risk of connection failure. The simplified design reduces material and manufacturing costs. At the same time, the independent signal input and output pins 123 provide flexibility for different control schemes. The unified power and ground designs help to reduce electromagnetic interference. By optimizing the electrical connection and structural layout, this embodiment improves the performance, reliability, and production efficiency of the matrix display 10, and also provides convenience for future expansion and maintenance.

It should be noted that the number of light-emitting dies 122 and driving chips 12 in FIG. 3 is only for illustration. Whether the pins 123 are fully covered is set according to time requirements, which is not limited by the embodiment of the present disclosure.

Exemplarily, as shown in FIGS. 3 and 5, the matrix display 10 further includes a first conductive sheet 17 and a second conductive sheet 18 disposed on the second surface of the insulating substrate 11; the first conductive sheet 17 includes a first conductive strip along the extending direction of the power pin 1232 and a plurality of first electrode fingers arranged at intervals on the first conductive strip; the second conductive sheet 18 includes a second conductive strip along the extending direction of the ground pin 1231 and a plurality of second electrode fingers arranged at intervals on the second conductive strip; wherein the first conductive strip and the second conductive strip are disposed oppositely; the plurality of first electrode fingers and the plurality of second electrode fingers are alternately arranged; at least one first electrode finger is electrically connected to the power pin 1232, and at least one second electrode finger is electrically connected to the ground pin 1231.

The above embodiment provides a larger contact area through the comb-shaped conductive sheet, improving the distribution of the power and ground. At the same time, the alternately arranged electrode fingers form an interlocking structure, which helps to reduce electromagnetic interference. The special conductive sheet design helps to optimize the impedance characteristics of the signal transmission line. The increased metal area helps to dissipate heat and improve the overall heat dissipation performance. And it reduces the distributed resistance of the power and ground, and enhances electrical performance. The optimized power and ground distribution helps to maintain signal integrity. And the alternately arranged design of the above embodiment improves space utilization efficiency. And the design of the electrode fingers provides flexibility for different connection needs, and multi-point connection increases the redundancy of the system and improves overall reliability. The increased conductive area also improves the power handling capacity of the system, and the alternately arranged structure produces a distributed capacitance effect, which helps to filter.

In summary, this design optimizes the distribution structure of the power and ground, improving the electrical performance, heat dissipation effect and signal integrity, while also facilitating manufacturing and future expansion. This structure is specifically developed for the provided high-performance and high-integration matrix display 10.

It should be noted that in some embodiments, the plurality of first electrode fingers are electrically connected to the power pin 1232, and the plurality of first electrode fingers electrically connected to the power pin 1232 are arranged at equal intervals; the plurality of second electrode fingers are electrically connected to the ground pin 1231, and the plurality of second electrode fingers electrically connected to the ground pin 1231 are arranged at equal intervals.

By means of the first conductive sheet 17 and the second conductive sheet 18 disposed on the second surface of the insulating substrate 11, as well as the design of alternately arranged electrode fingers, the power distribution, heat dissipation, signal integrity and other aspects of the entire system have been significantly optimized. This layout not only enhances the electrical performance but also enhances the anti-electromagnetic interference and heat dissipation capabilities, and meanwhile provides better support for the manufacturing process and equipment reliability. These technical features act synergistically, making the overall performance of the matrix display 10 more efficient, stable and reliable.

It should be noted that, as shown in FIG. 3, the insulating substrate 11 includes a plurality of conductive through-holes 111, and the provided matrix display 10 further includes a plurality of conductive posts 10a (such as copper posts). The electrical connection between the first electrode finger and the power pin 1232 can be realized by disposing the conductive posts 10a in the conductive through-holes 111.

Exemplarily, as shown in FIGS. 3, 4, and 5, the matrix display 10 further includes: a signal input unit 10b disposed on one side of the second surface of the insulating substrate 11, wherein the signal input unit 10b includes a plurality of signal input terminals 10b1 and a signal input interface 10b2 disposed on one side of the second surface, and the signal input interface 10b2 is electrically connected to the plurality of signal input terminals 10b1; a surface mount board, the surface mount board 19 is disposed on the second surface of the insulating substrate, the surface mount board 19 includes an input slot, and the signal input unit 10b is located in the input slot; wherein the signal input pin 1233 located on one side of the insulating substrate 11 is electrically connected to the signal input terminal 10b1; in each pin 123 group, the signal input pin 1233 and the signal output pin 123 of adjacent pin 123 pairs are integrally formed; a control signal is input to the signal input pin 1233 through the signal input unit 10b; and each driving chip 121 controls the corresponding light-emitting die 122 to emit light according to the control signal.

The above embodiment centrally processes signal input through the signal input unit 10b, simplifies the signal transmission path, and improves the stability and efficiency of signal transmission. The surface mount board design makes the signal input unit 10b stable and occupy less space, which helps to improve the integration of the system and reduce complex wiring. The integrally formed design of the signal input pin 1233 and the output pin 123 reduces the connection nodes in signal transmission, thereby reducing signal interference and helping to maintain signal integrity. The design of the surface mount board and the input slot makes the installation and fixing of the signal input unit 10b simpler, facilitating the assembly and maintenance of the equipment. At the same time, each driving chip 121 independently controls the light-emitting unit 12 according to the input control signal, providing precise control of the light-emitting state and improving the display effect of the matrix display 10. By reducing the number of connections between the independent pins 123, the integrally formed design reduces the risk of wire breakage or poor contact and improves the reliability of the equipment. The integrally formed pin 123 design simplifies the manufacturing process, reduces the number of required components, and lowers production costs. In summary, the above signal input and transmission design not only simplifies the system structure, but also improves the efficiency, stability, and reliability of signal transmission, and is suitable for the application scenario of high-performance LED matrix displays 10.

The matrix display provided by the embodiment of the present disclosure has at least the following beneficial effects:
a) Light control: The first light-shielding layer and the second light-shielding layer can block the side light of the light-emitting units; the light is mainly emitted from the second through-holes.
b) Improved display effect: By controlling the light emission direction, the display clarity and contrast are improved.
c) Prevention of light pollution: It reduces light scattering and light interference between displays.
d) Structural optimization: The design of the double layers of encapsulants and light-shielding layers improves the protection effect and service life of the LED.
e) Energy efficiency improvement: By controlling the light direction, the loss of invalid light is reduced, and the energy utilization efficiency is improved.

In summary, the design of the matrix display provided by the embodiment of the present disclosure realizes precise control of LED light emission through the structure of the multiple layers of encapsulants and light-shielding layers, which is expected to improve display quality, reduce light pollution, and bring improvements in energy efficiency and service life.

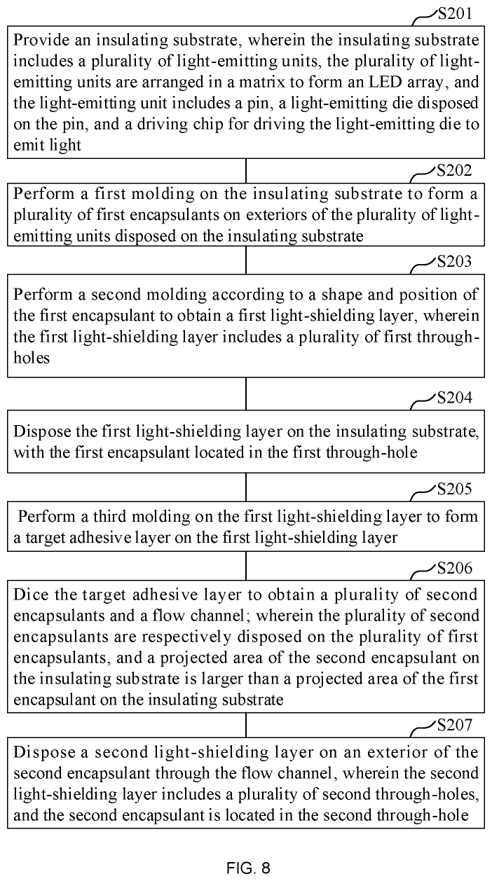

Please refer to FIG. 8, FIG. 8 is a schematic flow chart of the steps of the preparation method provided in an embodiment of the present disclosure. The provided method is used to prepare the matrix display corresponding to any one of the embodiments in FIGS. 1-7. As shown in FIG. 8, the provided method includes the following steps.

In step 201, provide an insulating substrate, wherein the insulating substrate includes a plurality of light-emitting units, the plurality of light-emitting units are arranged in a matrix to form an LED array, and the light-emitting unit includes a pin, a light-emitting die disposed on the pin, and a driving chip for driving the light-emitting die to emit light.

Specifically, provide an insulating substrate with a plurality of light-emitting units. The light-emitting units are arranged in a matrix to form an LED array. Each light-emitting unit includes a pin, a light-emitting die, and a driving chip. The provision of the initial substrate builds the foundation for the entire preparation process. Through the pre-arranged light-emitting units, the standardization and consistency of the array are ensured.

In step 202, perform a first molding on the insulating substrate to form a plurality of first encapsulants on exteriors of the plurality of light-emitting units disposed on the insulating substrate.

Specifically, by performing the first molding on the insulating substrate, a plurality of first encapsulants are formed on the exteriors of the plurality of light-emitting units. Through the first molding process, each light-emitting unit is encapsulated to protect it from environmental pollution and mechanical damage, and improve the durability and reliability of the light-emitting units.

In step 203, perform a second molding according to a shape and position of the first encapsulant to obtain a first light-shielding layer, wherein the first light-shielding layer includes a plurality of first through-holes.

Specifically, by performing the second molding according to the position and shape of the first encapsulant, a first light-shielding layer including a plurality of first through-holes is formed. The precise molding process ensures that the positions and sizes of the through-holes of the first light-shielding layer match the first encapsulant, which not only improves the light-shielding effect, but also reduces side light leakage.

In step 204, dispose the first light-shielding layer on the insulating substrate, with the first encapsulant located in the first through-hole.

Specifically, by disposing the first light-shielding layer on the insulating substrate it is ensured that the first encapsulant is located in the first through-hole. By disposing the first light-shielding layer, the light emitted non-forwardly is effectively blocked, and the light emission efficiency and display effect of the LED array are improved.

In step 205, perform a third molding on the first light-shielding layer to form a target adhesive layer on the first light-shielding layer.

Specifically, by performing the third molding on the first light-shielding layer, a target adhesive layer is formed. The third molding further encapsulates, protects the underlying components and forms a new encapsulation layer, thereby preparing for the subsequent dicing step.

In step 206, dice the target adhesive layer to obtain a plurality of second encapsulants and a flow channel; wherein the plurality of second encapsulants are respectively disposed on the plurality of first encapsulants, and a projected area of the second encapsulant on the insulating substrate is larger than a projected area of the first encapsulant on the insulating substrate.

Specifically, by dicing the target adhesive layer, a plurality of second encapsulants and a flow channel are obtained. The second encapsulants are respectively disposed on the first encapsulants, and their projected area on the insulating substrate is larger than that of the first encapsulants. Through precise dicing, the area and position of each second encapsulant are ensured, the protective performance and the control of the light emission direction are enhanced, and preparation is made for further disposing the light-shielding layer.

In step 207, dispose a second light-shielding layer on an exterior of the second encapsulant through the flow channel, wherein the second light-shielding layer includes a plurality of second through-holes, and the second encapsulant is located in the second through-hole.

Specifically, dispose a second light-shielding layer on exteriors of the second encapsulants through the flow channel, the second light-shielding layer includes a plurality of second through-holes, and the second encapsulants are located in the second through-holes. Through the disposition of the second light-shielding layer, the light emitted from the side is further blocked, ensuring that the light is only emitted from the second through-holes, improving the directionality and uniformity of light output, and enhancing the anti-interference ability of the equipment. The provided method encapsulates and protects the light-emitting unit layer by layer through multiple molding processes and the disposition of the light-shielding layers, effectively improving the structural integrity, optical performance, and durability of the LED array. By precisely controlling the positions and sizes of the encapsulants and the light-shielding layers, the effective emission direction of light is ensured, the display effect is optimized, and good environmental adaptability and anti-interference ability are provided. The entire manufacturing process achieves a high degree of integration and automation, which helps improve production efficiency and yield rate while reducing manufacturing costs.

In some embodiments, the shape of the first encapsulant corresponds to the shape of the first through-hole, and the shape of the second encapsulant corresponds to the shape of the second through-hole; wherein the projected shape of the first encapsulant on the insulating substrate is different from the projected shape of the second encapsulant on the insulating substrate.

In the above embodiment, the shape of the first encapsulant of the provided matrix display corresponds to the shape of the first through-hole, and the shape of the second encapsulant corresponds to the shape of the second through-hole. By making the projected shapes of the first encapsulant and the second encapsulant on the substrate different, the design of the light-shielding layers and the through-holes effectively blocks the light from exiting sideways, making the light mainly exit from the second through-holes, reducing light scattering, improving the directionality and uniformity of light emission, and enhancing the display effect. And through the design of double layers of encapsulants and different projected shapes, the light emission path is controlled, the display brightness and contrast are improved, and the interference or light pollution caused by light overflow is reduced. At the same time, the structure of multiple layers of the first encapsulant and the second encapsulant provides better physical protection for the light-emitting unit, which helps to extend the service life of the LED and enhance the ability to resist environmental influences. Through the innovative encapsulation and light-shielding design, this embodiment optimizes the light-emitting effect and service life of the LED matrix display and effectively improves the display quality.

Exemplarily, the projected shape of the first encapsulant on the insulating substrate is a circle, and the projected shape of the second encapsulant on the insulating substrate is a rectangle. Furthermore, the provided matrix display optimizes the light diffusion and focusing effect through the combined design of circular and rectangular shapes for the first encapsulant and the second encapsulant respectively, and improves the uniformity and clarity of display. The design of the rectangle located within the circle provides better light guidance and protection effects.

It should be noted that in some embodiments, the rectangle is located within the circle. The center of the rectangle coincides with the center of the circle. Furthermore, the symmetrical light output of the matrix display is ensured through the center coincidence design.

In some embodiments, the type of the first encapsulant is different from the type of the second encapsulant; the first encapsulant is either a transparent encapsulant or a diffusion encapsulant, and the second encapsulant is another one among a transparent encapsulant and a diffusion encapsulant which is different from the first encapsulant.

The transparent encapsulant has a high transmittance, which can effectively transmit the light emitted by the light-emitting unit, and improve the brightness and color purity of the emergent light. The diffusion encapsulant can effectively scatter light, making the light more uniform, reducing bright spots or dark spots, and improving the uniformity of the display effect. Through the combined use of different encapsulants, the high transmittance of the transparent encapsulant and the uniform light distribution effect of the diffusion encapsulant can be combined, so that the light-emitting unit can perform its best under the encapsulation of different layers, and the overall display effect can be optimized. The different type choices of the first encapsulant and the second encapsulant can more accurately control the light emission paths and scattering paths in the design, increase the design flexibility, and help achieve the best display effect. The use of different types of encapsulants also helps to improve the heat dissipation performance of the light-emitting unit. Certain encapsulants have higher thermal conductivity, which can effectively dissipate heat, thereby extending the life of the light-emitting unit. At the same time, the combined use of different types of encapsulants provides more design options, allowing engineers to have greater flexibility in designing and adjusting optical performance. By reasonably selecting the types of transparent encapsulant and diffusion encapsulant, the light efficiency can be improved while reducing the light interference on surrounding components, and the overall performance of the optical system can be further optimized. The provided matrix display can adapt to different usage scenarios and customer needs. In some cases, higher brightness light output is required, while in other cases, more uniform light distribution is required. Through this measure, the product characteristics can be flexibly adjusted according to the needs.

In summary, by adopting different types of encapsulants (the transparent encapsulant and the diffusion encapsulant) in the design of the matrix display 10 to optimize the optical performance of different layers, not only the display effect and optical performance of the LED matrix display 10 are enhanced, but also greater design flexibility and adaptability are provided. At the same time, it can effectively improve the reliability and service life of the product and meet the needs of different application scenarios.

In some embodiments, the thickness of the first through-hole is greater than or equal to the thickness of the first encapsulant. Furthermore, it is ensured that the first encapsulant is completely surrounded by the first through-hole, which helps to better control the initial diffusion and direction of light. And it provides sufficient space for the first encapsulant to prevent the encapsulant from overflowing or being squeezed, and protects the integrity of the light-emitting unit. By providing additional space for heat dissipation, it helps to improve the heat dissipation performance of the LED. It provides a certain tolerance space in the production process to facilitate the injection and molding of the encapsulant.

In some embodiments, the thickness of the second through-hole is greater than or equal to the thickness of the second encapsulant. Furthermore, it is ensured that the second encapsulant is completely located in the second through-hole, and the light emission path and angle are further precisely controlled. And it prevents the second encapsulant from protruding from the surface of the second light-shielding layer, maintains the flatness of the display surface, and improves the display quality. At the same time, the second through-hole completely surrounds the second encapsulant, maximizing the effect of the light-shielding layer and reducing light leakage. It provides sufficient space for the second encapsulant and enhances the stability and durability of the overall structure.

In some embodiments, the thickness of the first encapsulant is greater than or equal to the thickness of the second encapsulant. Furthermore, the thicker first encapsulant helps to initially diffuse and homogenize the light, while the thinner second encapsulant can further finely control the light emergence. The thicker first encapsulant provides better physical protection and insulation effect for the light-emitting unit. The thicker first encapsulant helps to better disperse and manage heat and to improve the life and performance of the LED. The thickness configuration provides more possibilities for optical design, and the light output characteristics can be optimized by adjusting the thickness ratio of the two layers of encapsulants. The thicker first encapsulant is easier to manufacture and mold, while the thinner second encapsulant is conducive to fine adjustment and surface treatment.

In summary, any combination of the above three embodiments according to requirements not only optimizes the optical performance and structural stability of the matrix display, but also improves the manufacturing feasibility and product durability. Through the elaborately designed thickness configuration, the present disclosure realizes precise control of light output, and at the same time provides sufficient protection and heat dissipation conditions for the matrix display.

In some embodiments, the insulating substrate and the first light-shielding layer are BT resin substrates. BT (Bismaleimide Triazine) resin is used as the material of the insulating substrate and the first light-shielding layer. BT resin has excellent heat resistance and can maintain stable performance in high-temperature environments. At the same time, due to its low dielectric constant, it helps to reduce signal interference and improve circuit performance. And it also has low moisture absorption, which can reduce the impact of moisture on the circuit and improve the reliability of the product. It can also enhance the stability and durability of the overall structure and ensure effective isolation between circuit components.

In some embodiments, the second light-shielding layer is a light-shielding adhesive layer. It provides better adaptability and processing convenience through the form of adhesive layers. It effectively controls the unintended light scattering and reduces the light interference between devices.

Exemplarily, the color of the light-shielding adhesive layer is black. As shown in FIG. 1, the black material can effectively absorb light of various wavelengths and greatly reduce light leakage. The black background enhances the visual effect of LED light emission and improves the display contrast.

It should be noted that in some embodiments, the color of the insulating substrate and the first light-shielding layer is white. The white surface can reflect the light emitted by the LED and improve the light utilization rate. At the same time, the reflection increases the overall brightness output of the matrix display and improves the display effect. The white surface helps to reflect heat, improve heat distribution, and facilitate the uniform diffusion of light, improving display uniformity. It can also increase light output through reflection and improve overall energy efficiency.

The above embodiments create an efficient, high-contrast display system through combination according to requirements. The BT resin substrate provides good electrical and mechanical properties. The black light-shielding adhesive layer ensures precise light control and high contrast, while the white insulating substrate and the first light-shielding layer optimize light utilization and thermal management. This design not only improves display quality and energy efficiency, but also enhances the overall performance and reliability of the device.

In the description of the present disclosure, it should be noted that, unless otherwise expressly specified and defined, the terms “mounting”, “connection” and “coupling” shall be construed in a broad sense. For example, they may refer to a fixed connection, a detachable connection, or an integral connection; they may refer to a mechanical connection or an electrical connection; they may refer to a direct connection, or an indirect connection via an intermediate medium; or, they may refer to a communication between the interiors of two elements or an interaction relationship between two elements. For a person of ordinary skill in the art, the specific meanings of the above terms in the present disclosure can be understood according to specific circumstances.

The disclosure above provides a variety of different embodiments or examples for implementing the various structures of the present disclosure. To simplify the present disclosure, the components and arrangements of specific examples are described hereinabove. These are merely illustrative examples and are not intended to limit the present disclosure. In addition, the present disclosure may repeat reference numerals and/or reference letters in different examples; such repetition is for the sake of simplicity and clarity, and does not in itself indicate a relationship between the various embodiments and/or arrangements discussed. Furthermore, the present disclosure provides examples of various specific processes and materials, but a person of ordinary skill in the art will appreciate the applicability of other processes and/or the use of other materials.

In the description of this specification, the description with reference to the terms “one embodiment”, “some embodiments”, “exemplary embodiments”, “examples”, “specific examples”, or “some examples” etc. means that the specific features, structures, materials, or characteristics described in conjunction with the embodiments or examples are included in at least one embodiment or example of the present disclosure. In this specification, the schematic representations of the aforesaid terms do not necessarily refer to the same embodiment or example. Furthermore, the specific features, structures, materials or characteristics described may be combined in any suitable manner in any one or more embodiments or examples.

What is claimed is:

1. A matrix display, comprising:
an insulating substrate;
a plurality of light-emitting units, disposed on the insulating substrate and arranged in a matrix to form an LED array, wherein the light-emitting unit comprises a pin, a light-emitting die disposed on the pin, and a driving chip for driving the light-emitting die to emit light;
a plurality of first encapsulants, each first encapsulant is encapsulated on an exterior of each light-emitting unit;
a first light-shielding layer, disposed on the insulating substrate, comprising a plurality of first through-holes, and the first encapsulant is located in the first through-hole;
a plurality of second encapsulants, each second encapsulant is encapsulated on each first encapsulant, wherein a projected area of the second encapsulant on the insulating substrate is larger than a projected area of the first encapsulant on the insulating substrate;
a second light-shielding layer, disposed on the first light-shielding layer, comprising a plurality of second through-holes, wherein the second encapsulant is located in the second through-hole;
wherein, when the plurality of light-emitting units emit light, the first light-shielding layer and the second light-shielding layer can block light emitted by the light-emitting unit from exiting sideways, thereby making the light exit from the second through-hole.

2. A matrix display according to claim 1, wherein a shape of the first encapsulant corresponds to a shape of the first through-hole, and a shape of the second encapsulant corresponds to a shape of the second through-hole; wherein a projected shape of the first encapsulant on the insulating substrate is different from a projected shape of the second encapsulant on the insulating substrate.

3. A matrix display according to claim 2, wherein the projected shape of the first encapsulant on the insulating substrate is a circle, and the projected shape of the second encapsulant on the insulating substrate is a rectangle.

4. A matrix display according to claim 3, wherein the rectangle is located within the circle, and a center of the rectangle coincides with a center of the circle.

5. A matrix display according to claim 1, wherein a type of the first encapsulant is different from a type of the second encapsulant, the first encapsulant is either a transparent encapsulant or a diffusion encapsulant, and the second encapsulant is another one among the transparent encapsulant and the diffusion encapsulant which is different from the first encapsulant.

6. A matrix display according to claim 1, wherein a thickness of the first through-hole is greater than or equal to a thickness of the first encapsulant; or
a thickness of the second through-hole is greater than or equal to a thickness of the second encapsulant; or
a thickness of the first encapsulant is greater than or equal to a thickness of the second encapsulant.

7. A matrix display according to claim 6, wherein a color of the light-shielding adhesive layer is black.

8. A matrix display according to claim 7, wherein a color of the insulating substrate and the first light-shielding layer is white.

9. A matrix display according to claim 1, wherein the insulating substrate comprises a first surface and a second surface opposite to each other; a plurality of rows of pin groups are arranged at intervals on the first surface of the insulating substrate, and each row of pin groups comprises a plurality of pin pairs; each pin pair comprises a power pin, a ground pin, a signal input pin, and a signal output pin; the light-emitting die and the driving chip are electrically connected to the power pin; the driving chip is electrically connected to the ground pin, the signal input pin, and the signal output pin respectively; wherein the power pins of the plurality of pin pairs are integrally formed, and the ground pins of the plurality of pin pairs are integrally formed.

10. A matrix display according to claim 9, further comprising:
a first conductive sheet, disposed on the second surface of the insulating substrate, comprising a first conductive strip along an extending direction of the power pin and a plurality of first electrode fingers arranged at intervals on the first conductive strip;
a second conductive sheet, disposed on the second surface of the insulating substrate, comprising a second conductive strip along an extending direction of the ground pin and a plurality of second electrode fingers arranged at intervals on the second conductive strip;
wherein the first conductive strip and the second conductive strip are disposed oppositely; the plurality of first electrode fingers and the plurality of second electrode fingers are alternately arranged; at least one first electrode finger is electrically connected to the power pin, and at least one second electrode finger is electrically connected to the ground pin.

11. A matrix display according to claim 10, wherein the plurality of first electrode fingers are electrically connected to the power pin, and the plurality of first electrode fingers electrically connected to the power pin are arranged at equal intervals; the plurality of second electrode fingers are electrically connected to the ground pin, and the plurality of second electrode fingers electrically connected to the ground pin are arranged at equal intervals.

12. A matrix display according to claim 9, further comprising:
a signal input unit, disposed on one side of the second surface of the insulating substrate, comprising a plurality of signal input terminals and a signal input interface disposed on one side of the second surface, wherein the signal input interface is electrically connected to the plurality of signal input terminals;
a surface mount board, disposed on the second surface of the insulating substrate, comprising an input slot, wherein the signal input unit is located in the input slot;
wherein the signal input pin located on one side of the insulating substrate is electrically connected to the signal input terminal; in each pin group, the signal input pin and the signal output pin of adjacent pin pairs are integrally formed; a control signal is input to the signal input pin through the signal input unit; and each driving chip controls the corresponding light-emitting die to emit light according to the control signal.

13. A preparation method for a matrix display, comprising:
providing an insulating substrate, wherein the insulating substrate comprises a plurality of light-emitting units, the plurality of light-emitting units are arranged in a matrix to form an LED array, and the light-emitting unit comprises a pin, a light-emitting die disposed on the pin, and a driving chip for driving the light-emitting die to emit light;
performing a first molding on the insulating substrate to form a plurality of first encapsulants on exteriors of the plurality of light-emitting units disposed on the insulating substrate;
performing a second molding according to a shape and position of the first encapsulant to obtain a first light-shielding layer, wherein the first light-shielding layer comprises a plurality of first through-holes;
disposing the first light-shielding layer on the insulating substrate, with the first encapsulant located in the first through-hole;
performing a third molding on the first light-shielding layer to form a target adhesive layer on the first light-shielding layer;
dicing the target adhesive layer to obtain a plurality of second encapsulants and a flow channel; wherein the plurality of second encapsulants are respectively disposed on the plurality of first encapsulants, and a projected area of the second encapsulant on the insulating substrate is larger than a projected area of the first encapsulant on the insulating substrate; and
disposing a second light-shielding layer on an exterior of the second encapsulant through the flow channel, wherein the second light-shielding layer comprises a plurality of second through-holes, and the second encapsulant is located in the second through-hole.

14. A preparation method according to claim 13, wherein a shape of the first encapsulant corresponds to a shape of the first through-hole, and a shape of the second encapsulant corresponds to a shape of the second through-hole; wherein a projected shape of the first encapsulant on the insulating substrate is different from a projected shape of the second encapsulant on the insulating substrate.

15. A preparation method according to claim 14, wherein the projected shape of the first encapsulant on the insulating substrate is a circle, and the projected shape of the second encapsulant on the insulating substrate is a rectangle.

16. A preparation method according to claim 15, wherein the rectangle is located within the circle, and a center of the rectangle coincides with a center of the circle.

17. A preparation method according to claim 13, wherein a type of the first encapsulant is different from a type of the second encapsulant, the first encapsulant is either a transparent encapsulant or a diffusion encapsulant, and the second encapsulant is another one among the transparent encapsulant and the diffusion encapsulant which is different from the first encapsulant.

18. A preparation method according to claim 13, wherein the insulating substrate and the first light-shielding layer are BT resin substrates; or, the second light-shielding layer is a light-shielding adhesive layer.

19. (canceled)

20. (canceled)

21. A matrix display according to claim 1, wherein the insulating substrate and the first light-shielding layer are BT resin substrates; or, the second light-shielding layer is a light-shielding adhesive layer.

22. A preparation m ethod according to claim 14, wherein a thickness of the first through-hole is greater than or equal to a thickness of the first encapsulant; or
a thickness of the second through-hole is greater than or equal to a thickness of the second encapsulant; or
a thickness of the first encapsulant is greater than or equal to a thickness of the second encapsulant.
